(19) United States
(12) Patent Application Publication
(10) Pub. No.: US 2007/0033473 A1
(43) Pub. Date: Feb. 8, 2007

(54) LSI inspection module, control method for LSI inspection module, communication method between LSI inspection module and inspection apparatus, and LSI inspection method

(75) Inventor: Wataru Ito, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/476,565

(22) Filed: Jun. 29, 2006

(30) Foreign Application Priority Data
Jul. 4, 2005 (JP) 2005-194725

(51) Int. Cl. G01R 31/28; G06F 11/00

(52) U.S. Cl. 714/738

(57) ABSTRACT

In an LSI inspection module, an I/O interface compatible with the I/O interface of an LSI as an inspection target is provided and testing data is stored in a memory for test data. During inspection, an LSI inspection apparatus controls the interface control circuit of the inspection module by setting the value of a status control flag and performs the outputting of the testing data to the target LSI and the reading of result data outputted from the target LSI in accordance with the testing data.

### CROSS REFERENCE TO RELATED APPLICATIONS

The teachings of Japanese Patent Application JP 2005-194725, filed Jul. 4, 2005, are entirely incorporated herein by reference, inclusive of the specification, drawings, and claims.

### BACKGROUND OF THE INVENTION

1. Field of the Invention

The present invention relates to an LSI inspection module for generating testing data for a functional inspection performed by using an LSI inspection apparatus.

2. Description of the Prior Art

A conventional LSI inspection apparatus generates a test pattern (testing data) consisting of binary numbers, stores the generated test pattern in a memory, and inputs the stored test pattern to an LSI as an inspection target. By comparing the binary testing data consequently outputted from the LSI with an expected value, the conventional LSI inspection apparatus has performed the functional inspection of the LSI. Such an LSI inspection apparatus has the problem that the length of the test pattern (pattern capacity) is increased when an amount of writing and reading to be performed to the LSI during inspection is extremely large. In particular, the pattern capacity for the recent system LSI has remarkably increased. However, there have been cases where the increased pattern capacity has made it impossible for, e.g., a low-cost LSI inspection apparatus to perform a sufficient functional inspection because of the limited memory capacity for storing the test pattern and the like.

To prevent this, an LSI inspection apparatus for inspecting, e.g., an asynchronous LSI (LSI which performs the inputting/outputting of data, while performing handshake with a communication partner) has been proposed. The LSI inspection apparatus for the asynchronous LSI has distributed the operation of generating a test pattern between dedicated hardware for generating a simple test pattern and a versatile computer for generating a complicated test pattern and thereby reduced the capacity of the test pattern to be stored in the memory (see, e.g., Japanese Laid-Open Patent Publication No. 2002-156419).

However, the above-mentioned LSI inspection apparatus having the dedicated hardware for generating the test pattern has had the problem that it supports only the writing of data to the asynchronous LSI and cannot support either an LSI having a synchronous I/O interface (I/O) interface which performs an operation in synchronization with a clock signal) or the reading of data outputted from the LSI with the synchronous I/O interface.

### SUMMARY OF THE INVENTION

The present invention has been achieved in view of the problem mentioned above and it is therefore an object of the present invention to allow an LSI inspection module for generating testing data for an LSI inspection to generate the testing data irrespective of whether the input/output of an LSI as an inspection target is synchronous or asynchronous.

To solve the problem mentioned above, a first aspect of the present invention is an LSI inspection module for generating testing data for a functional inspection performed by using an LSI inspection apparatus, the LSI inspection module comprising: an I/O interface compatible with an I/O interface of an LSI as an inspection target; an interface control circuit for controlling inputting and outputting of data to and from the LSI inspection apparatus and inputting and outputting of data between the I/O interface and the target LSI; and a memory for test data in which the testing data is stored.

The arrangement allows the generation of testing data irrespective of whether or not the input/output of the target LSI is synchronous or asynchronous. As a result, a complicated functional inspection can be performed with respect to the LSI even when an LSI inspection apparatus having a small memory capacity for storing the testing data is used.

A second aspect of the present invention is the LSI inspection module in the first aspect of the present invention, further comprising: an expected value memory for storing an expected value to be outputted from the target LSI in accordance with the testing data; and a result determination circuit for comparing result data with the expected value stored in the expected value memory and outputting a signal indicating a pass or fail as a result of determination to the LSI inspection apparatus.

A third aspect of the present invention is the LSI inspection module in the second aspect of the present invention, further comprising: a determination result memory for storing the result of determination from the result determination circuit, wherein the result determination circuit is constituted to collectively output a plurality of the results of determination to the LSI inspection apparatus.

Since the result of inspection is thus processed in the LSI inspection module, the determination of the result in the LSI inspection apparatus becomes simple.

A fourth aspect of the present invention is an LSI inspection method using an LSI inspection module for generating testing data for a functional inspection performed by using an LSI inspection apparatus, wherein the LSI inspection module comprises: an I/O interface compatible with an I/O interface of an LSI as an inspection target; an interface control circuit for controlling inputting and outputting of data to and from the LSI inspection apparatus and inputting and outputting of data between the I/O interface and the target LSI; a memory for test data in which the testing data is stored; an expected value memory for storing an expected value to be outputted from the target LSI in accordance with the testing data; and a result determination circuit for comparing result data with the expected value stored in the expected value memory and outputting a signal indicating a pass or fail as a result of determination to the LSI inspection apparatus, the LSI inspection method comprising the step of: determining which one of an operation of writing the testing data to the target LSI and an operation of reading the result data is to be performed in accordance with the result of determination from the result determination circuit.

As a result, the writing of the testing data to the target LSI or the reading of the result data therefrom is performed in accordance with the result of determination (i.e., the operating state of the target LSI) from the result determination circuit. This allows a bilateral inspection to be performed between the target LSI and the inspection module.

A fifth aspect of the present invention is a control method for an LSI inspection module for generating testing data for a functional inspection performed by using an LSI inspection apparatus, wherein, when the functional inspection includes both of a writing operation and a reading operation, the LSI inspection module comprises: an I/O interface compatible with an I/O interface of an LSI as an inspection target; an interface control circuit for controlling inputting and outputting of data to and from the LSI inspection apparatus and inputting and outputting of data between the I/O interface and the target LSI; and a memory for test data in which the testing data is stored, the control method comprising the step of: controlling an operation of the interface control circuit by using a status signal which indicates an inspection status in the LSI inspection apparatus and which has been outputted to the interface control circuit via a status control flag connecting respective signal channels of the interface control circuit and the LSI inspection apparatus.

The arrangement allows the LSI inspection apparatus to control the operation of the LSI inspection module.

A sixth aspect of the present invention is a communication method between an LSI inspection module for generating testing data for a functional inspection performed by using an LSI inspection apparatus and the LSI inspection apparatus, wherein the LSI inspection module comprises: an I/O interface compatible with an I/O interface of an LSI as an inspection target; an interface control circuit for controlling inputting and outputting of data to and from the LSI inspection apparatus and inputting and outputting of data between the I/O interface and the target LSI, while converting result data outputted from the target LSI in accordance with the testing data to data smaller in capacity than the result data and outputting the data smaller in capacity to the LSI inspection apparatus; and a memory for test data in which the testing data is stored, the communication method comprising the step of: transmitting the result data to the LSI inspection apparatus by using an output control flag connecting respective signal channels of the interface control circuit and the LSI inspection apparatus.

The arrangement allows easy exchange of the result of inspection and the like between the LSI inspection apparatus and the LSI inspection module.

### BRIEF DESCRIPTION OF THE DRAWINGS

FIG. 1 is a block diagram showing a structure of an inspection module according to a first embodiment of the present invention;

FIG. 2 is a block diagram showing a structure of an inspection module according to a second embodiment of the present invention;

FIG. 3 is a block diagram showing a variation of the inspection module according to the second embodiment; and

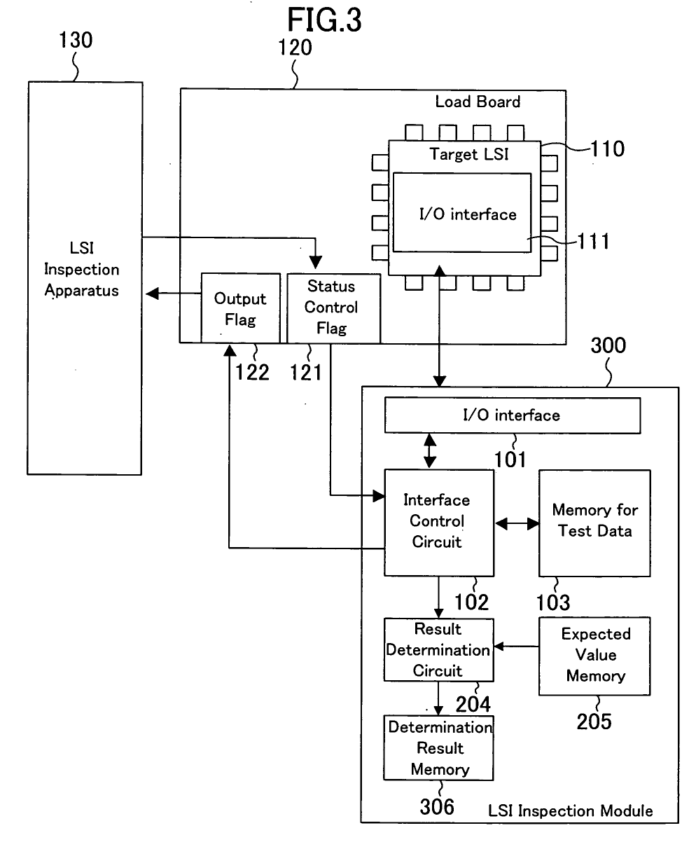

FIG. 4 is a view showing a control flow when a bilateral inspection is performed by using the inspection module according to the second embodiment.

### DETAILED DESCRIPTION OF THE PREFERRED EMBODIMENTS

Referring to the drawings, the embodiments of the present invention will be described herein below.

### Embodiment 1

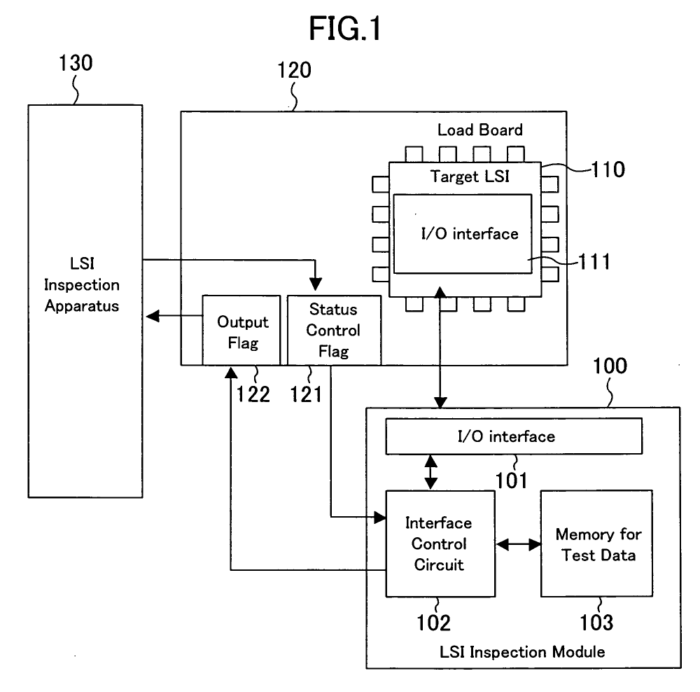

FIG. 1 is a block diagram showing a structure of an inspection module 100 according to a first embodiment of the present invention. The inspection module 100 outputs testing data (test pattern) for inspecting an LSI 110 as an inspection target to the target LSI 110 under the control of an LSI inspection apparatus 130. The inspection module 100 reads result data outputted from the target LSI 110 in accordance with the above-mentioned testing data. The result data that has been read is outputted to the LSI inspection apparatus 130 such that the LSI inspection apparatus 130 determines the result of inspection.

The target LSI 110 comprises an I/O interface 111 and inputs/outputs data to and from the outside via the I/O interface 111. During inspection, the target LSI 110 is mounted on a load board 120 and connected to the inspection module 100.

Specifically, the inspection module 100 is comprised of: an I/O interface 101; an interface control circuit 102; and a memory 103 for testing data, as shown in detail in FIG. 1.

The I/O interface 101 performs the writing of the above-mentioned testing data and the reading of the above-mentioned result data with respect to the I/O interface 111 of the target LSI 110. Thus, the I/O interface 101 is an I/O interface compatible with the I/O interface 111 of the target LSI 110.

The interface control circuit 102 controls the I/O interface 101 in accordance with the value of a status flag 121 (which will be described later) and performs the writing of the above-mentioned testing data to the target LSI 110 and the reading of the above-mentioned result data therefrom. In addition, the interface control circuit 102 converts the result data that has been read to simpler data (data smaller in capacity than the above-mentioned result data) and outputs the simpler data to the LSI inspection apparatus 130 via an output flag 122 (which will be described later).

The memory 103 for testing data stores the testing data.

The load board 120 comprises the status control flag 121 and the output flag 122 and allows the target LSI 110 to be mounted thereon for the inspection thereof.

The status control flag 121 is a flag used by the LSI inspection apparatus 130 to control the target LSI 110 and the inspection module 100 during inspection. Specifically, the status control flag 121 indicates the current status of inspection, which is any of a “write status” for the above-mentioned testing data, a “read status” for the above-mentioned result data, and a “wait state”.

The output flag 122 stores data outputted from the interface control circuit 102.

In the inspection module 100 thus constituted, when the testing data is written in the target LSI 110, the LSI inspection apparatus 130 sets the status control flag 121 to the “write status”. As a result, the testing data stored in the memory 103 for test data is read therefrom by the interface control circuit 102 and outputted to the target LSI 110 via the I/O interface 101. Consequently, the result data in accordance with the testing data is outputted from the target LSI 110 via the I/O interface 111.

When the result data outputted from the target LSI 110 is read, the LSI inspection apparatus 130 sets the status control flag 121 to the “read status”. As a result, the result data outputted from the target LSI 110 is read by the interface control circuit 102 via the I/O interface 101. The result data that has been read is converted to simpler data by the interface control circuit 102 and outputted to the LSI inspection apparatus 130 via the output flag 122. Then, the LSI inspection apparatus 130 determines the inspection result.

In the inspection module 100, when the writing of the testing data to the target LSI 110 or the reading of the result data therefrom is performed, the LSI inspection apparatus 130 is in the wait status or performing only the reception of data from the output flag 122. Accordingly, the memory (pattern memory) for test data of the LSI inspection apparatus 130 is in a loop state or has a short read pattern. Thus, the present embodiment allows a significant reduction in the length of the test pattern stored in the LSI inspection apparatus 130.

If data sets to be written and read via the I/O interface 111 are described in binary test patterns, they are extremely complicated. However, the LSI inspection apparatus 130 obviates the need to generate complicated test patterns since it performs the writing and reading of data by using the inspection module 100 composed of a hardware item.

In addition, the inspection module 100 having the I/O interface 101 compatible with the I/O interface 111 allows inspection irrespective of whether the input/output of the target LSI 110 is synchronous or asynchronous.

### Embodiment 2

A description will be given to an example of an inspection module constituted to perform the determination of the result data in addition to the generation of the testing data.

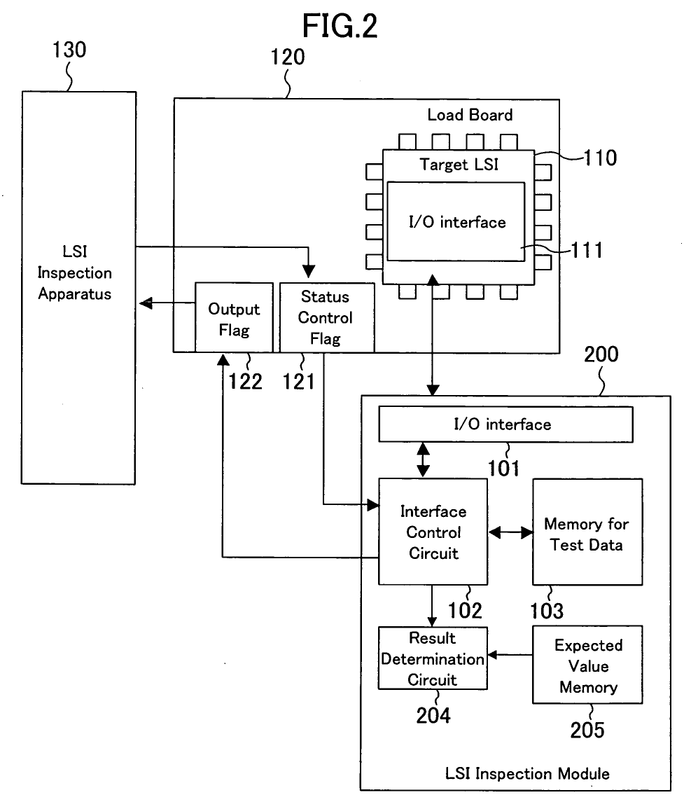

FIG. 2 is a block diagram showing a structure of an inspection module 200 according to the second embodiment of the present invention. In the following embodiment, the description of the components having the same functions as in the first embodiment described above will be omitted by retaining the same reference numerals. As shown in FIG. 2, the inspection module 200 has been obtained by adding a result determination circuit 204 and an expected value memory 205 to the inspection module 100.

The result determination circuit 204 compares the result data converted to simpler data by the interface control circuit 102 with an expected value for the testing data preliminarily stored in the expected value memory 205 and outputs the result of comparison to the output flag 122.

The inspection module 200 thus constituted allows the transmission of only the signal indicating “Pass” or “Fail” to the LSI inspection apparatus 130. Thus, the present embodiment simplifies the determination of the result in the LSI inspection apparatus 130 and allows a reduction in the length of the test pattern stored in the LSI inspection apparatus 130.

In the case where there are a plurality of the results of reading relative to the testing data, the inspection module 200 may also comprise an additional determination result memory 306.

In the arrangement, the results of determination performed by the result determination circuit 204 are accumulated in the determination result memory 306 and the accumulated data sets are collectively outputted to the LSI inspection apparatus 130 so that a further reduction is achieved in the length of the test pattern stored in the LSI inspection apparatus 130.

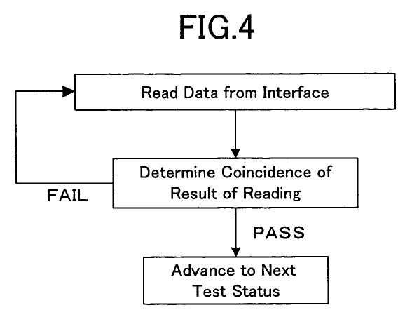

The writing of the testing data and the reading of the result data in the inspection module 200 may also be controlled in accordance with the flow shown in FIG. 4. The control allows a bilateral inspection to be performed between the target LSI 110 and the inspection module 200.

The bilateral inspection between the target LSI 110 and the inspection module 200 can be implemented by, e.g., providing a sufficient waiting time in the case where the subsequent operation is guaranteed the internal status of the target LSI 110.

That is, in the flow shown in FIG. 4, data is first read from the I/O interface 101. When the result of determination by the result determination circuit 204 is “Fail”, the same data is repeatedly read and a change in the internal status of the target LSI 110 is monitored. When the result of determination by the result determination circuit 204 is “Pass”, it shows that the internal status of the target LSI 110 has changed so that the test flow advances to the next status.

Thus, the test flow described above moves to the next status after properly recognizing the internal status of the target LSI 110. As a result, it becomes possible to perform the bilateral inspection between the target LSI 110 and the inspection module 200.

Thus, the LSI inspection module, the control method for the LSI inspection module, the communication method between the LSI inspection module and the LSI inspection apparatus, and the LSI inspection method according to the present invention allow the generation of the testing data irrespective of whether the input/output of the target LSI is synchronous or asynchronous. As a result, the present invention achieves the effect of allowing a complicated functional test to be performed with respect to the LSI even when an LSI inspection apparatus having a small memory capacity for storing the testing data is used and is therefore useful as an LSI inspection module for generating testing data for a functional inspection performed by using an LSI inspection apparatus or the like.

What is claimed is:

1. An LSI inspection module for generating testing data for a functional inspection performed by using an LSI inspection apparatus, the LSI inspection module comprising:
an I/O interface compatible with an I/O interface of an LSI as an inspection target;
an interface control circuit for controlling inputting and outputting of data to and from the LSI inspection apparatus and inputting and outputting of data between the I/O interface and the target LSI; and
a memory for test data in which the testing data is stored.

2. The LSI inspection module of claim 1, further comprising:
an expected value memory for storing an expected value to be outputted from the target LSI in accordance with the testing data; and
a result determination circuit for comparing result data with the expected value stored in the expected value memory and outputting a signal indicating a pass or fail as a result of determination to the LSI inspection apparatus.

3. The LSI inspection module of claim 2, further comprising:
a determination result memory for storing the result of determination from the result determination circuit, wherein
the result determination circuit is constituted to collectively output a plurality of the results of determination to the LSI inspection apparatus.

4. An LSI inspection method using an LSI inspection module for generating testing data for a functional inspection performed by using an LSI inspection apparatus, wherein the LSI inspection module comprises:
an I/O interface compatible with an I/O interface of an LSI as an inspection target;
an interface control circuit for controlling inputting and outputting of data to and from the LSI inspection apparatus and inputting and outputting of data between the I/O interface and the target LSI;
a memory for test data in which the testing data is stored;
an expected value memory for storing an expected value to be outputted from the target LSI in accordance with the testing data; and
a result determination circuit for comparing result data with the expected value stored in the expected value memory and outputting a signal indicating a pass or fail as a result of determination to the LSI inspection apparatus, the LSI inspection method comprising the step of:
determining which one of an operation of writing the testing data to the target LSI and an operation of reading the result data is to be performed in accordance with the result of determination from the result determination circuit.

5. A control method for an LSI inspection module for generating testing data for a functional inspection performed by using an LSI inspection apparatus, wherein, when the functional inspection includes both of a writing operation and a reading operation, the LSI inspection module comprises:
an I/O interface compatible with an I/O interface of an LSI as an inspection target;
an interface control circuit for controlling inputting and outputting of data to and from the LSI inspection apparatus and inputting and outputting of data between the I/O interface and the target LSI; and
a memory for test data in which the testing data is stored, the control method comprising the step of:
controlling an operation of the interface control circuit by using a status signal which indicates an inspection status in the LSI inspection apparatus and which has been outputted to the interface control circuit via a status control flag connecting respective signal channels of the interface control circuit and the LSI inspection apparatus.

6. A communication method between an LSI inspection module for generating testing data for a functional inspection performed by using an LSI inspection apparatus and the LSI inspection apparatus, wherein the LSI inspection module comprises:
an I/O interface compatible with an I/O interface of an LSI as an inspection target;
an interface control circuit for controlling inputting and outputting of data to and from the LSI inspection apparatus and inputting and outputting of data between the I/O interface and the target LSI, while converting result data outputted from the target LSI in accordance with the testing data to data smaller in capacity than the result data and outputting the data smaller in capacity to the LSI inspection apparatus; and
a memory for test data in which the testing data is stored, the communication method comprising the step of:
transmitting the result data to the LSI inspection apparatus by using an output control flag connecting respective signal channels of the interface control circuit and the LSI inspection apparatus.
